(19) United States
(12) Patent Application Publication
(10) Pub. No.: US 2003/0166334 A1
(43) Pub. Date: Sep. 4, 2003

(54) Bond pad and process for fabricating the same

(76) Inventors: Ming-Yu Lin, Hsinchu (TW); Lien-Che Ho, Hsinchu (TW); Mao-l Ting, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/065,630

(22) Filed: Nov. 5, 2002

Related U.S. Application Data
(60) Provisional application No. 60/357,489, filed on Feb. 14, 2002.

(51) Int. Cl. H01L 21/4763

(52) U.S. Cl. 438/627

(57) ABSTRACT

A bond pad of a semiconductor device and a process for fabricating the same are provided. On a semiconductor base is formed a plurality of disconnected insulation blocks that are defined by a plurality of channels. The disconnected insulation blocks are arranged in a grid or helix form. A barrier layer is formed over the disconnected insulation blocks and the semiconductor base. A conductive layer is formed over the disconnected insulation blocks to fill the channels, such that a topography of the conductive layer is similar to that of the underlying structure.

### CROSS REFERENCE TO RELATED APPLICATIONS

This application claims the priority benefit of U.S. provisional application serial No. 60/357,489, filed on Feb. 14, 2002, all disclosures are incorporated therewith.

### BACKGROUND OF INVENTION

1. Field of the Invention

The present invention relates to a method of fabricating a semiconductor device, and more specifically, to the forming a bond pad for the connection of a semiconductor device to an external conductive wire at a bond site.

2. Description of the Related Art

In a conventional process for fabricating the bond pad, an upper conductive layer is formed over a substrate. Then, an interlayer dielectric (ILD) layer is formed on the upper conductive layer. One or more than one contact structures are formed through the ILD layer to electrically connect the bond pad and the upper conductive layer.

During a wire bonding process, the bond pad would be fractured and the ILD would be delaminated from the bond pad due to the force of wire bonding. Therefore, undesirable poor electrical connection occurs.

### SUMMARY OF INVENTION

It is one object of the present invention to provide a bond pad and a process for fabricating the bond pad, in which stress fracture of the bond pad can be prevented.

It is another object of the present invention to provide a bond pad and a process for fabricating the bond pad, in which an attenuation in the amount of stress encountered by the ILD layer, when for example the bond pad and bond wire are adhesively attached, can thus be achieved using the structure of the present invention.

It is still another object of the present invention to provide a bond pad and a process for fabricating the bond pad, in which electromigration is minimized.

It is still yet another object of the present invention to provide a bond pad and a process for fabricating the bond pad, in which an adhesive strength between layers is enhanced.

It is still another object of the present invention to provide a bond pad and a process for fabricating the bond pad, in which delamination and lifting of bond pad are minimized.

It is still another object of the present invention to provide a bond; pad and a process for fabricating the bond pad, in which the size of a bond wire or a ball may be reduced without significantly weakening the bond, resulting in an increased density of bond pad on a single device.

In one aspect of the present invention, a bond pad is provided having an upper conductive layer, a plurality of disconnected dielectric blocks, and a topmost conductive layer. The disconnected dielectric blocks are arranged on the upper conductive layer, spaced apart from one another. Preferably, the disconnected dielectric blocks are arranged in a specific manner, such as a grid or helix form. Preferably, a barrier layer is conformal to the upper conductive layer that has the plurality of disconnected dielectric blocks thereon. A conductive material is filled or partially filled between the disconnected dielectric blocks. The topmost conductive layer is located over the mentioned-above structure.

In another aspect of the present invention, a bond pad of a semiconductor device is provided. The semiconductor device has at least a semiconductor element protected by a first insulation layer. The bond pad is located on the first insulation layer and electrically connected to the underlying semiconductor element. The bond pad includes a semiconductor base, a second insulation layer, a conductive layer and a third insulation layer, which are sequentially laminated on the semiconductor base. The second insulation layer is defined to form a plurality of disconnected insulation blocks that are defined by a plurality of channels. The conductive layer is formed over the disconnected insulation blocks to fill the channels. The third insulation layer is formed over the conductive layer, leaving a portion of the conductive layer exposed.

In still another aspect of the present invention, a process for fabricating a bond pad is provided. An interlayer dielectric (ILD) layer is deposited on an upper conductive layer. The ILD layer is defined to form a plurality of disconnected dielectric blocks. A barrier layer is formed on the disconnected dielectric blocks and ILD layer. A conductive material is filled between the disconnected dielectric blocks. A metal layer is formed over the disconnected dielectric blocks and the conductive material and then defined to form a plurality of bond pads.

In accordance with the present invention, the barrier layer acts as a glue layer to aid in the adhesion of future metal layers to existing layers. It also reduces the occurrence of electromigration. Furthermore, the grid structure of the bond pad can minimize delamination or lifting of the bond pad, which may otherwise occur between the metal layer and the barrier layer due to the fabrication processes. This can reduce the likehood of future separation of the bond wire or ball from the bond pad. As a consequence of the stronger cohesion, the size of the bond wire or ball may be reduced to increase density of bond pad on a single device.

### BRIEF DESCRIPTION OF DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 is a cross-sectional view of a semiconductor device in an intermediate process step according one embodiment of the present invention;

FIG. 2 is a plan view of the device of FIG. 1 after a dielectric layer has been etched into a grid pattern to expose portions of an underlying conductive layer;

FIG. 3 is a cross-sectional view of the semiconductor device of FIG. 2 after deposition of a barrier layer and further processing according one embodiment of the present invention;

FIG. 4 is a perspective view of the semiconductor device of FIG. 3;

FIG. 5 is a cross-sectional view of the semiconductor device of FIG. 2 after a layer of aluminum has been deposited according to one embodiment of the present invention;

FIG. 6 is a perspective view of the semiconductor device of FIG. 5 in which a wire bond is connected to the bond pad according to one embodiment of the present invention; and

FIG. 7 is a plan view of a semiconductor die connected to a plurality of conductive wires according to another embodiment of the present invention.

### DETAILED DESCRIPTION

Reference will now be made in detail to the present preferred embodiments of the invention, examples of which are illustrated in the accompanying drawings. Whenever possible, the same reference numbers are used in the drawings and the description to refer to the same or like parts. It should be noted that the drawings are in simplified form and are not to precise scale. In reference to the disclosure herein, for purposes of convenience and clarity only, directional terms, such as top, bottom, left, right, up, down, over, above, below, beneath, rear, and front are used with respect to the accompanying drawings. Such directional terms should not be constructed to limit the scope of the invention in any manner.

Although the disclosure herein refers to certain illustrated embodiments, it is to be understood that these embodiments are presented by way of example and not by way of limitation. The intent of the following detailed description is to cover all modifications, alternatives, and equivalents as may fall within the spirit and scope of the invention as defined by the appended claims. For example, it is understood by a person of ordinary skill practicing this invention that the bond pads fabricated in accordance with the present invention may be connected to bond wires directly, or solder or gold bumps may be formed on the bond sites for tape-automated bonding. Different barrier materials, different dielectrics, different conductive and metal layers, and different combinations thereof, can thus be implemented in accordance with the present invention.

It is to be understood and appreciated that the process steps and structures described herein do not cover a complete process flow for the fabrication of bond pad structure. The present invention may be practiced in conjunction with various integrated circuit fabrication techniques that are conventionally used in the art, and only so much of the commonly practiced process steps are included herein as are necessary to provide an understanding of the present invention.

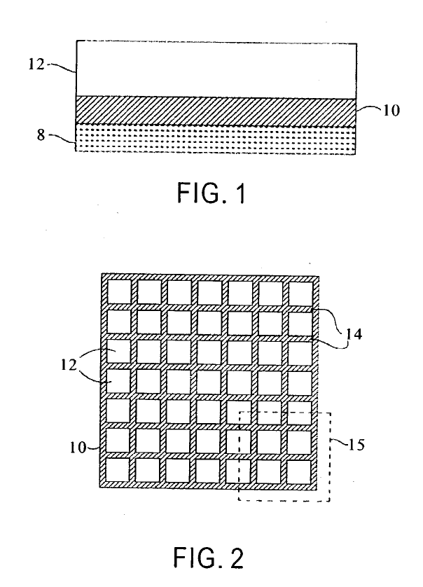

FIG. 1 illustrates a cross-sectional view of a semiconductor device in an intermediate process step according one embodiment of the present invention. As illustrated, the semiconductor device has been subject to a number of processing steps, one of which was the application of an upper conductive layer 10 over a plurality of previously formed layers which may include a field oxide layer 8. The field oxide layer 8 can comprise, for example, silicon dioxide (SiO₂) formed using aknown technique, such as thermal oxidation or chemical vapor deposition (CVD).

The device exists on a substrate (not shown), which typically comprises p-type or n-type doped silicon, in the form of a wafer. Although the substrate preferably comprises a silicon substrate, in alternative embodiments, the substrate can comprise materials such as gallium nitride (GaN), gallium arsenide (GaAs), or other materials commonly recognized as suitable semiconductor materials to those skilled in the art. An interlayer dielectric (ILD) layer 12 has been coated using conventional means over the upper conductive layer 10, which may comprise materials such as polysilicon, copper, or aluminum. A material of the ILD layer 12 can comprise materials selected from those standard in the art such as spin on glass (SOG), borophosphosilicate glass (BPSG), or silicon dioxide (SiO₂).

A photoresist is then deposited onto the structure of FIG. 1 through the use of a spinner. A photolithographic process using a stepper or mask aligner in conjunction with appropriate photomask is then performed, wherein ultraviolet (UV) light is irradiated onto predetermined, unmasked areas of the wafer. The wafer is then placed into a developer bath, which dissolves the photoresist that has been depolymerized (for positive photoresist) or that has not been polymerized (for negative photoresist) by the UV light, revealing a specific pattern in the photoresist.

The ILD 12 is subsequently anisotropically etched using a process such as reactive ion etching (RIE), and the pattern in the photoresist is thereby transferred to the ILD 12. As presently embodied, the etch process etches completely through areas of the ILD 12 that are exposed by the patterned photoresist and stops at the upper conductive layer 10. Following the etch process, the photoresist is removed using a standard ash and clean procedure. FIG. 2 shows an over view of a grid pattern formed by etching the ILD 12. As illustrated, channels 14 which are the portions etched off from the ILD 12 define a plurality of disconnected dielectric blocks which form the grid pattern 15. The pattern defined by the channels 14 is not limited to the grid shape as shown in FIG. 2, and can be in the helix form, or any other proper continued shapes. That is, the blocks formed by the channel could be of any shapes. The channels, even in any shapes, are connected as one continued channel as a whole.

In an example of the prior art, a plurality of via structures are formed to electrically couple the bond pad to the underlying conductive layer 10. The bonding process can produce increased levels of thermal and structural strain due to properties such as the inconsistent coefficients of thermal expansion between the ILD 12 and other layers, which can cause for example the formation of stress fractures in the ILD 12.

The grid pattern 15 formed in accordance with the present invention reduces the net present of the ILD 12. For instance, with the inter-dispersion of a barrier layer 17 between a tungsten layer 19 and the ILD layer 12, expansion and contraction inconsistency between the ILD layer 12 and the tungsten layer 19 can be better tolerated. Decrease in the amount of stress encountered by the ILD layer 12, when for example the bond pad and bond wire are adhesively attached, can thus be achieved using the structure of the present invention.

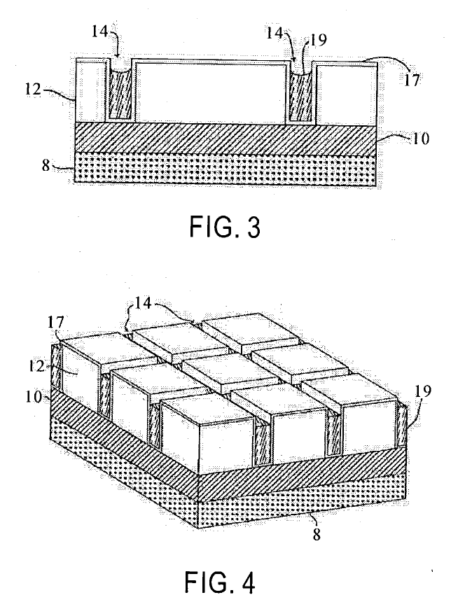

As illustrated in FIG. 3, the barrier layer 17 is deposited onto the patterned ILD 12 and the upper conductive layer 10. The barrier layer 17 may comprise titanium (Ti), titanium nitride (TiN), Ti/TiN, tantalum nitride (TaN), wolfram nitride (WN), molybdenum nitride (MON), silicon nitride (SiN), or silicon oxynitride (SiON). As used herein, Ti/TiN refers to either a titanium layer which has been annealed in a nitrogen atmosphere to at least partially convert the titanium to titanium nitride, or a thin titanium layer on which is deposited a thin TiN layer by a separate process step.

In one embodiment of the present invention, the barrier layer 17 is formed by sputtering or CVD a TiN layer to a substantially uniform thickness on the ILD 12 and the upper conductive layer 10. The TiN is a hard, dense and refractory material that provides a relatively high electrical conductivity. In accordance with the present invention, the barrier layer 17 acts as a glue layer to aid in the adhesion of future metal layers to existing layers. It also prevents the tungsten layer 19 from spiking into the upper conductive layer 10 or the ILD 12, and reduces the occurrence of electromigration. In the case that the barrier layer 17 is deposited, the barrier layer 17, the channels 14 and the disconnected dielectric blocks constitute the grid pattern 15 in a similar way as illustrated in the above embodiment.

The barrier layer 17 is then covered with a conductive material, which exhibits an acceptable step coverage such as tungsten, by for example physical vapor deposition (PVD), sputtering, or CVD. Preferably, the tungsten layer 19 is deposited to-fill the channels 14 to approximately 60% to 90% of their capacity. In this embodiment, the channels 14 are only partially filled, so that a resulting topography of the wafer is non-planar. Thereby, the thickness difference between the tungsten layer 19 and the barrier layer 17 is significant to define surface features. In an alternative embodiment, the channels 14 may be completely filled with tungsten.

After the tungsten layer 19 has been deposited, the tungsten layer 19 over the ILD 12 is partially removed by a chemical-mechanical planarization (CMP) process, leaving the tungsten layer 19 only in the channels 14. As known to those having skill in the semiconductor processing art, CMP is an abrasive process, performed on oxides and metals, that is used to remove uneven surface materials and polish the surface of the wafer flat. Chemical slurries can be used along with a circular “sanding” action to create a smooth surface and, in the present case, to remove predetermined portions of the tungsten layer 19.

In the alternative embodiment of the present invention in which the channels 14 are completely filled with the tungsten layer 19, CMP is omitted. An etchant that has a relatively high selectivity for the tungsten layer 19 with respect to the barrier layer 17 is used to remove a portion of the tungsten layer 19 from the ILD layer 12. Thus, the barrier layer 17 in this case serves as an etch stop.

In another embodiment of the present invention in which the channels 14 are initially completely filled, the tungsten layer 19 over the ILD 12 can be removed by CMP and/or etching, to thereby yield an essentially planar surface extending over both the ILD 12 and the channels 14. The resulting structure preferably comprises a plurality of disconnected dielectric blocks higher than the tungsten-filled channels 14 to form a grid pattern.

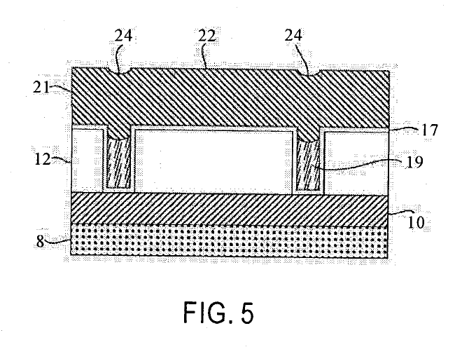

As illustrated in FIG. 5, a metal layer 21 is then deposited onto the wafer. An example of the metal layer 21 includes a highly conductive metal such as aluminum (Al), copper (Cu), gold (Ag) or an alloy of a combination thereof and/or other trace elements. In accordance with the present invention, the disconnected dielectric blocks, which are defined by the channels 14, and higher than the tungsten layer 19 inside the channels 14, increase adhesive strength between the tungsten layer 19, the barrier layer 17 and the metal layer 21. Moreover, the metal layer 21 is not only deposited onto the barrier layer 17, but also deposited onto the tungsten layer 19 in the channels 14. Therefore, on the surface of the metal layer 21 are formed raised surfaces 22 and indentations 24. The raised surfaces 22 are substantially conformal to the contour of the disconnected dielectric blocks that are covered by the barrier layer 17. The indentations 24 are substantially conformal to the contour of the channels 14 that are filled or partially filled with the tungsten layer 19.

The various processes, especially the bonding of the bond pad to the bond wire, impart mechanical stress and thermal energy to the bond pad. The bond pad with the grid pattern can minimize delamination or lifting of the bond pad, which may otherwise occur between the metal layer 21 and the barrier layer 17 due to the fabrication processes. The above problem is known to exist for essentially all types of bond technology, including aluminum wire bonding, gold bump bonding, and gold ball bonding.

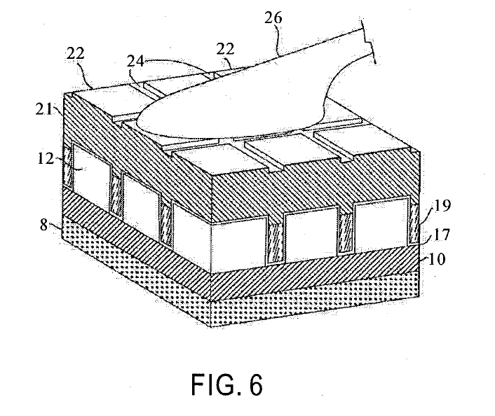

The indentations 24 exist in the metal layer 21 as shown in FIG. 5, due to the existing topography of the underlying layers. FIG. 6 illustrates a perspective view of the same structure of FIG. 5. The topography of the metal layer 21 exhibits the underlying contour constituting of the disconnected dielectric blocks, the channels 13, the barrier layer 17 and tungsten layer 19.

The metal layer 21 serves as a bond pad for connecting the semiconductor device to pins, which can then be attached to a printed circuit board. To define bonding regions of each bond pad for the semiconductor device, another photolithography step is performed. A photoresist is formed over the metal layer 21 and is subsequently exposed to UV radiation in a stepper or mask aligner. The photoresist is depolymerized and then dissolved to define a patterned photoresist. The metal layer 21 is etched by, for example, RIE to transfer the photoresist pattern to the metal layer 21. After the photoresist is removed, the resulting structure defines each bond pad of the device. A topmost passivation layer such as borophosphosilicate (BPSG) (not shown) may be then applied and patterned to leave the desired bond site of the bond pad for external electrical connection.

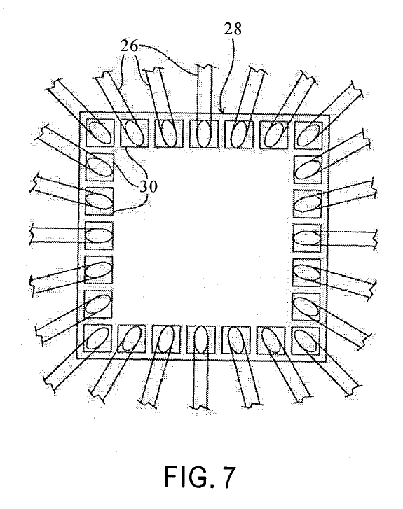

Electrical connection to the die can be accomplished in one of many ways, each of which may apply to the present invention. In a tape automated bonding (TAB) packaging process, the chip package includes a lead frame having a plurality of conductive leads, each typically provided with gold or solder bumps. The lead frame includes a die receiving area which is located so that the conductive leads align with their respective bond pads on the die. In another type of package, the package includes a die receiving area having a plurality of conductive leads. The conductive leads are geometrically disposed, usually in a radial fashion to align with each bond pad on the die. Thin aluminum or gold bond wires are then used to connect each bond pad to each conductive lead on a one-to-one basis. FIG. 7 shows a plan view of a semiconductor die 28 having a plurality of bond pads 30. Each bond pad 30 is mechanically and electrically connected to a conductive bond wire 26 (either made of gold or aluminum, for example). The bond wire 26 is radially disposed about the semiconductor die 28 such that no wires are in contact with one another.

With reference to FIG. 6, the contoured surface of the bond pad may provide advantageous bonding properties over the prior art. When a bond pad 26 or ball is adhesively attached to the bond pad, the contoured surface can provide a greater surface area for the bonding, resulting in stronger cohesion. This can reduce the likehood of future separation of the bond wire 26 or ball from the bond pad. As a consequence of the stronger cohesion, the size of the bond wire 26 or ball may be reduced without significantly weakening the bonding strength. This construction may allow for an increased density of bond pad on a single device.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

1. A process for fabricating a bond pad, comprising:
depositing an interlayer dielectric layer (ILD) on an upper conductive layer;
defining the ILD to form a plurality of disconnected dielectric blocks;
forming a barrier layer on the disconnected dielectric blocks and the upper conductive layer;
depositing a conductive material between the disconnected dielectric blocks; and
forming a metal layer over the disconnected dielectric blocks and the conductive material to form a plurality of bond pads.

2. The process of claim 1, wherein
the disconnected dielectric blocks are arranged in a grid form, wherein the disconnected dielectric blocks are separated by a plurality of channels;
the conductive material is deposited in the channels; and
the metal layer is formed over the disconnected dielectric blocks arranged in the grid form.

3. The process of claim 2, wherein the conductive material is deposited to fill the channels to approximately 60% to 90% of their capacity.

4. The process of claim 1, wherein a material for the upper conductive layer includes polysilicon.

5. The process of claim 1, wherein the conductive material includes tungsten.

6. The process of claim 1, wherein a material for the metal layer includes aluminum.

7. The process of claim 1, further comprising steps of forming a passivation layer over the bond pads; and defining a plurality of openings to expose bond sites respectively for the bond pads.

8. The process of claim 7, wherein a material for the passivation layer includes borophosphosilicate glass.

9. A bond pad of a semiconductor device that has at least a semiconductor element protected by a first insulation layer, the bond pad being located on the first insulation layer and electrically connected to the underlying semiconductor element, the bond pad comprising:
a semiconductor base laminated on the first insulation layer,
a plurality of disconnected insulation blocks on the semiconductor base,
wherein the disconnected insulation blocks are defined by a plurality of channels;
a conductive layer over the disconnected insulation blocks to fill the channels; and
a third insulation layer over the conductive layer, leaving a portion of the conductive layer exposed.

10. The bond pad of claim 9, wherein a material for the passivation layer includes borophosphosilicate glass.

11. The bond pad of claim 9, wherein the conductive layer further comprising a barrier layer conformal to the disconnected insulation blocks and the channels.

12. The bond pad of claim 9, wherein the conductive layer further comprising a tungsten substance filled in the channels, and a metal material covering the disconnected insulation blocks and tungsten filled in the channels, wherein the metal material is selected from the group consisting of highly conductive metals.

13. The bond pad of claim 12, wherein the metal material is aluminum.

14. The bond pad of claim 12, wherein the disconnected insulation blocks are arranged in a grid form.

15. The bond pad of claim 12, wherein the disconnected insulation blocks are arranged in a helix form.
